(19) United States
(12) Patent Application Publication
(10) Pub. No.: US 2025/0251317 A1
(43) Pub. Date: Aug. 7, 2025

(54) FAN VENTED ENCLOSURE SAMPLING SYSTEM

(71) Applicants: Analog Devices, Inc., Wilmington, MA (US); Analog Devices International Unlimited Company, Limerick (IE)

(72) Inventors: Neal T. Kurfiss, II, Newburyport, MA (US); Jonathan Ephraim David Hurwitz, Edinburgh (GB)

(73) Assignees: Analog Devices, Inc., Wilmington, MA (US); Analog Devices International Unlimited Company, Limerick (IE)

(21) Appl. No.: 19/046,783

(22) Filed: Feb. 6, 2025

Related U.S. Application Data
(60) Provisional application No. 63/550,981, filed on Feb. 7, 2024.

(51) Int. Cl. G01N 1/22; H05K 7/20

(52) U.S. Cl. CPC G01N 1/2226; H05K 7/20736

(57) ABSTRACT

A method and apparatus can include: a fan vented enclosure with cooling fans for creating air columns, each of the air columns corresponding to one of the cooling fans; a detector coupled to the fan vented enclosure; and an angled channel coupled to the fan vented enclosure, the angled channel configured to redirect a sample across at least one of the air columns to the detector such that a number of detectors is less than a number of air columns, the angled channel further configured to allow bypass air to flow around the angled channel.

### TECHNICAL FIELD

This disclosure relates to fan ventilated enclosures, more particularly to channels for sampling gas within the fan ventilated enclosure.

### BACKGROUND

Data-centers contain multiple individual hardware cases, also known as fan vented enclosures or servers, which house the computing resources of the data-center. One important metric in assessing data-center performance is the down-time of the computing resources.

Reducing down-time within data-centers has been identified as critical to providing competitive service in terms of price and performance. One source of down-time within data-centers is the ability to timely and properly respond to fire and smoke events within the data-center.

It is therefore strongly desirable to obtain immediate and localized information pertaining to the origin of a fire event or smoke event at the level of an individual vented enclosure within the data-center. A major hurdle in determining and localizing smoke events within a vented enclosure arises due to the vented enclosures themselves.

The vented enclosures contain multiple high velocity cooling fans which can move massive amounts of air and which can result in air columns moving at up to sixty kilometers per hour at the back of the fans. The air columns can be fast and can be isolated.

Consequently, previous solutions were expensive, which prohibited their implementation in practice. For example, one previous solution placed a smoke detector at each fan or exit port of the vented enclosure due to airflow within the case being isolated to air columns that are confined in-line with each fan.

These air columns make it difficult to place smoke sensors such that the number of sensors required is less than the number of fans. Placing a smoke sensor on every fan or exit port has not shown to be a practical economic solution and a need still remains for a solution which can be economically implemented within vast data-centers. Average full-scale data-centers can operate hundreds of thousands of individual servers, with each of these servers having multiple cooling fans.

Other previous solutions included walls or other structures placed within the vented enclosure; however, these walls and structures can often restrict the overall flow within the case and negatively impact the cooling efficiency within the vented enclosure. Previous solutions failed to provide an economically practical solution that could be relied upon to solve the problem of smoke detection at the level of a vented enclosure without negatively impacting the cooling efficiency within the vented enclosure.

Solutions have been long sought but prior developments have not taught or suggested any complete solutions, and solutions to these problems have long eluded those skilled in the art. Thus, there remains a considerable need for devices and methods that can provide economically practical, immediate, and localized information pertaining to the origin of a fire event or smoke event, anywhere within a vented enclosure, without negatively impacting the cooling efficiency of the vented enclosure.

### BRIEF DESCRIPTION OF DRAWINGS

The vented enclosure sampling system, herein referred to as the “sampling system”, is illustrated in the figures of the accompanying drawings which are meant to be exemplary and not limiting, in which like reference numerals are intended to refer to like components, and in which:

FIG. 1 is a front isometric view of the sampling system in a first embodiment.

FIG. 2 is an inverted cone for use with an embodiment of the sampling system.

FIG. 3 is a left side isometric view of the sampling system in a second embodiment and showing the angled channel in a first embodiment.

FIG. 4 is a front isometric view of the sampling system in a third embodiment.

FIG. 5 is a front isometric view of the sampling system in a fourth embodiment.

FIG. 6 is a front isometric view of the sampling system in a fifth embodiment.

FIG. 7 is a method of manufacturing the sampling system.

FIG. 8 is a cross-sectional view of the angled channel in a second embodiment.

FIG. 9 is a cross-sectional view of the angled channel in a third embodiment.

FIG. 10 is a cross-sectional view of the angled channel in a fourth embodiment.

FIG. 11 is a cross-sectional view of the angled channel in a fifth embodiment.

FIG. 12 is a cross-sectional view of the angled channel in a sixth embodiment.

FIG. 13 is a top view of the angled channel for implementation with an embodiment of the angled channel.

FIG. 14 is a top view of the angled channel for implementation with an embodiment of the angled channel.

FIG. 15 is a front isometric view of the sampling system in a sixth embodiment.

FIG. 16 is a top cross-sectional view of the sampling system in a seventh embodiment.

FIG. 17 is a top cross-sectional view of the sampling system in an eighth embodiment.

FIG. 18 is a top cross-sectional view of the sampling system in a ninth embodiment.

### DETAILED DESCRIPTION

In the following description, reference is made to the accompanying drawings that form a part hereof, and in which are shown by way of illustration, embodiments in which the sampling system may be practiced. It is to be understood that other embodiments may be utilized and structural changes may be made without departing from the scope of the sampling system.

When features, aspects, or embodiments of the sampling system are described in terms of steps of a process, an operation, a control flow, or a flow chart, it is to be understood that the steps can be combined, performed in a different order, deleted, or include additional steps without departing from the sampling system as described herein.

The sampling system is described in sufficient detail to enable those skilled in the art to make and use the sampling system and provide numerous specific details to give a thorough understanding of the sampling system; however, it will be apparent that the sampling system may be practiced without these specific details.

In order to avoid obscuring the sampling system, some well-known system configurations and descriptions are not disclosed in detail. Likewise, the drawings showing embodiments of the system are semi-diagrammatic and not to scale and, particularly, some of the dimensions are for the clarity of presentation and are shown greatly exaggerated in the drawing FIGs. As used herein, the term coupled is defined as direct or indirect contact between elements.

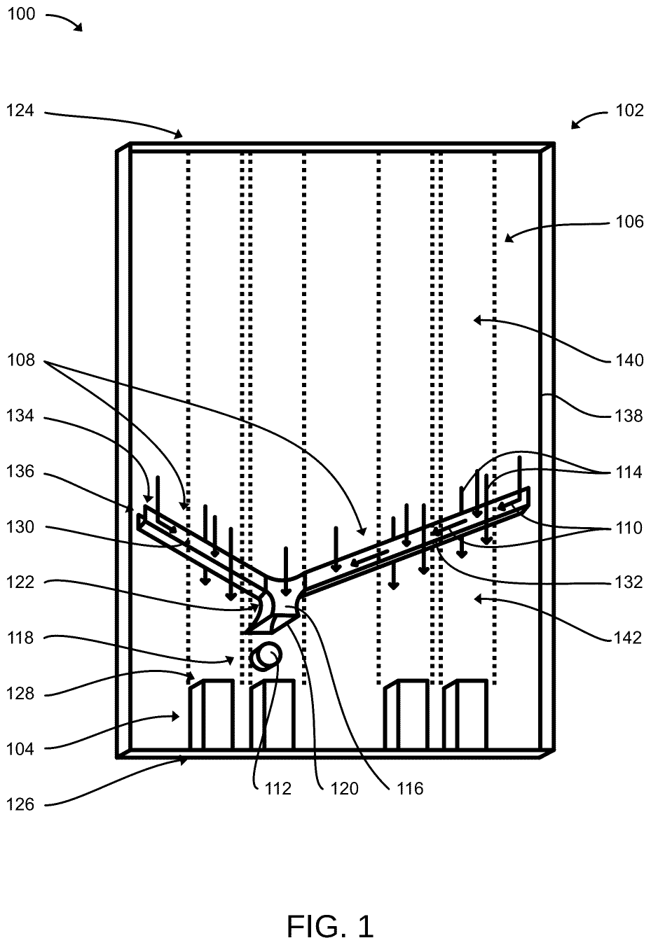

Referring now to FIG. 1, therein is shown a front isometric view of the sampling system 100 in a first embodiment. The sampling system 100 is shown having a vented enclosure 102.

The vented enclosure 102 can be a fan vented server including cooling fans 104. The cooling fans 104 can be powerful, high-velocity fans which create isolated air columns 106 within the vented enclosure 102.

Extending across multiple air columns 106 within the vented enclosure 102, angled channels 108 are depicted. The angled channels 108 are a mechanical apparatus that can re-direct samples 110 of air from within the air columns 106, and across the air columns 106, to a detector 112. The samples 110 can also be pulled into the angled channels 108 from air outside the more quickly moving air columns 106.

The detector 112 can be any type of sensor including a smoke detector, a gas detector, an aerosol detector, or other detector for suspended particles. Illustratively for example, the detector 112 can detect smoke from the combustion of a computing component within the vented enclosure 102 or could detect aerosols of vaporized capacitors from within the vented enclosure 102.

It has been discovered that implementing the angled channel 108 within the vented enclosure 102 does not impact the overall cooling efficiency of the vented enclosure 102. One reason for this is that the angled channel 108 collects the sample 110 but also allows other air from the air columns 106 to bypass the angled channel 108.

This bypass air 114 continues with little interruption within the air column 106. Since the bypass air 114 is minimally impeded, redirected, or otherwise changed, the cooling efficiency remains outstanding. The cross-sectional size of the angled channels 108 is a small fraction in relation to the cross-sectional size of the air column 106 and the height of the vented enclosure 102 so as to minimize the overall impact to airflow within the case.

The bypass air 114 is shown bypassing the angled channels 108 on two sides while the sample 110 is collected from the middle. Notably, the angled channels 108 can extend across all the air columns 106 and across an entire width of the vented enclosure 102 allowing the samples 110 to be collected from the entire width of the vented enclosure 102.

The samples 110 can be redirected to the detector 112 through an inverted cone 116. The inverted cone 116 produces a low pressure region 118 near a bottom 120 of the inverted cone 116 and high velocity air near a top 122 of the inverted cone 116 which pulls air, smoke, aerosols, and suspended particles along the angled channels 108 and into the inverted cone 116.

Connecting the inverted cone 116 to the angled channels 108 therefore provides a high velocity intake along the angled channels 108. It has been discovered that the inverted cone 116 can increase the velocity of air within the angled channels 108 so that there is no pressure build up and airflow can be maintained within the vented enclosure 102 without degrading cooling efficiency.

The detector 112 can be positioned within the low pressure region 118, which can be between the inverted cone 116 and one of the cooling fans 104. The vented enclosure 102 can also include enclosure input ports 124 and enclosure exit ports 126 with the air columns 106 flowing therebetween. The air columns 106 do not generally mix within the vented enclosure 102 but rather flow in a direct path from the enclosure input ports 124 to the enclosure exit ports 126.

It is contemplated that each of the enclosure input ports 124 will correspond with one of the enclosure exit ports 126 and one of the cooling fans 104. Each of the cooling fans 104 can include a fan intake 128 where the air columns 106 are pulled into the cooling fans 104. The cooling fans 104 can terminate at the enclosure exit ports 126 where the cooling fans 104 exhaust the air columns 106 at speeds that can reach up to sixty kilometers per hour.

The angled channels 108 can include channel sidewalls 130, a channel bottom 132, a channel open top 134, and a channel open end 136. The channel sidewalls 130 are depicted as two walls extending from the channel bottom 132 to terminate in the channel open top 134.

As shown, the angled channels 108 can have a squared off cross-sectional shape with the channel bottom 132 being the same width as the channel open top 134; however, it is also contemplated that the channel sidewalls 130 could be slanted with the channel bottom 132 being narrower than the channel open top 134. The channel open end 136 can terminate near an enclosure wall 138 of the vented enclosure 102 while the other end of the angled channels 108 can terminate at the inverted cone 116.

The top 122 of the inverted cone 116 can be narrow in relation to the larger bottom 120 in order to create the low pressure region 118 near the bottom 120 of the inverted cone 116. The angled channels 108 can terminate at the top 122 of the inverted cone 116 with the channel sidewalls 130 and channel bottom 132 in direct contact with the inverted cone 116.

The top 122 of the inverted cone 116 can also be open similar to the channel open top 134 and can accept the samples 110 directly from the air column 106 through the top 122. The angled channels 108 can be slanted or angled down toward the detector 112.

The moving air within the air columns 106 can create air that is upwind 140 being closer to the enclosure input ports 124 and air that is downwind 142 being closer to the enclosure exit ports 126.

The channel open top 134 can face upwind 140. Furthermore, the channel open end 136 can be further upwind 140 relative to the end of the angled channel 108 coupled to the inverted cone 116. The inverted cone 116 is depicted downwind 142 to the angled channels 108.

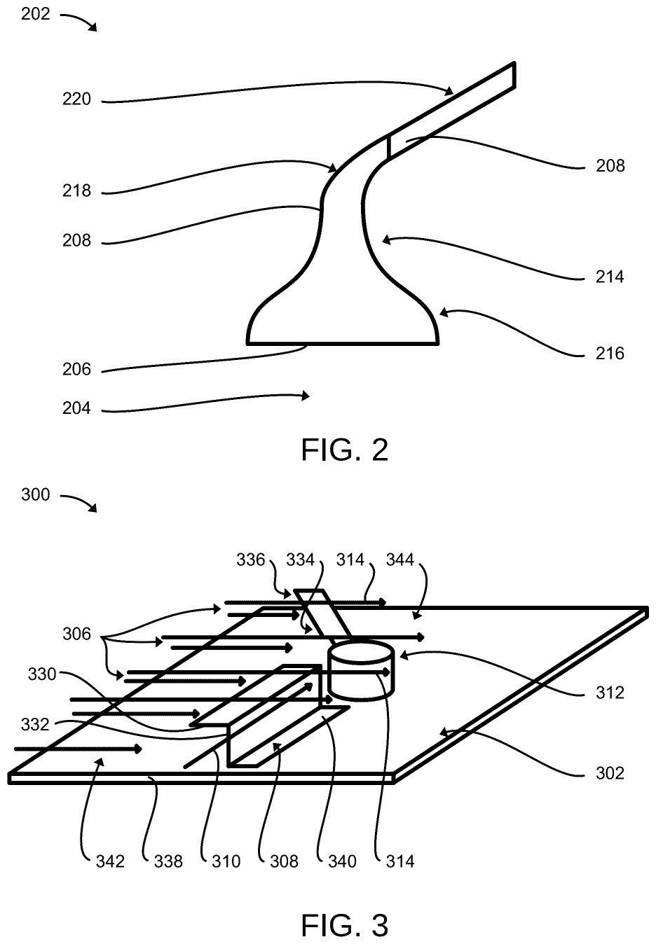

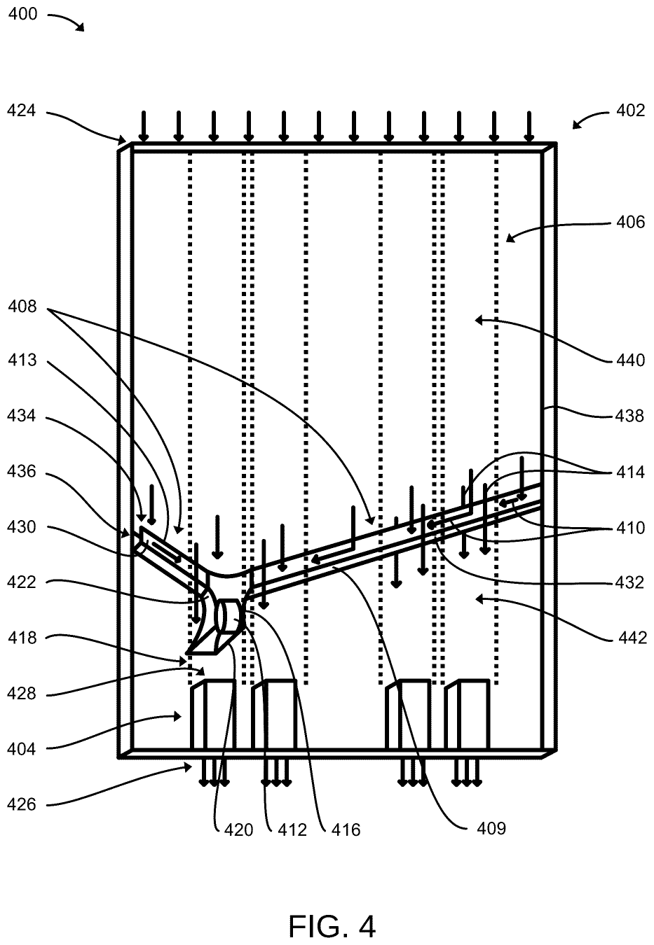

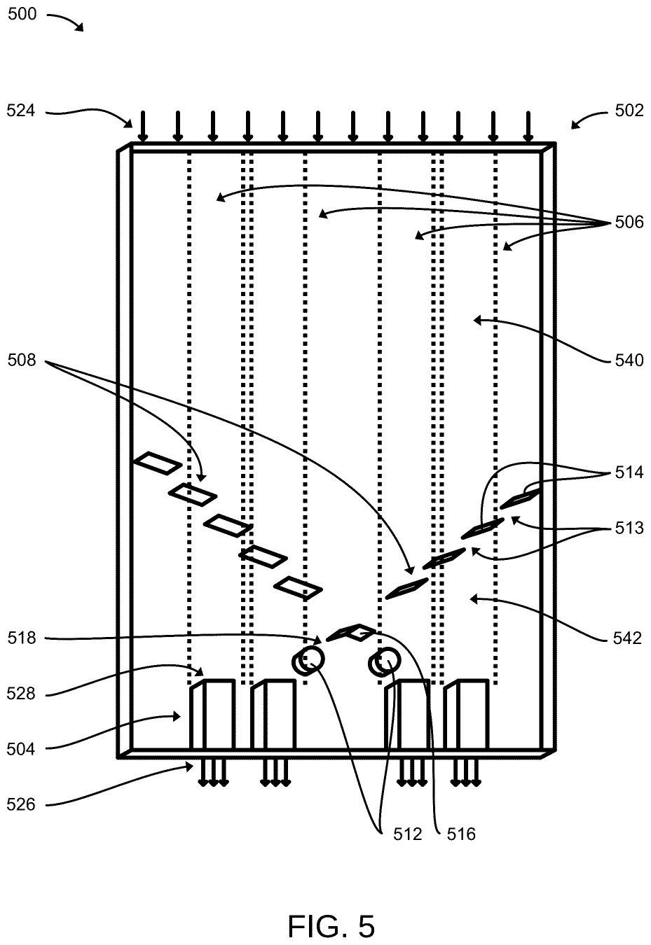

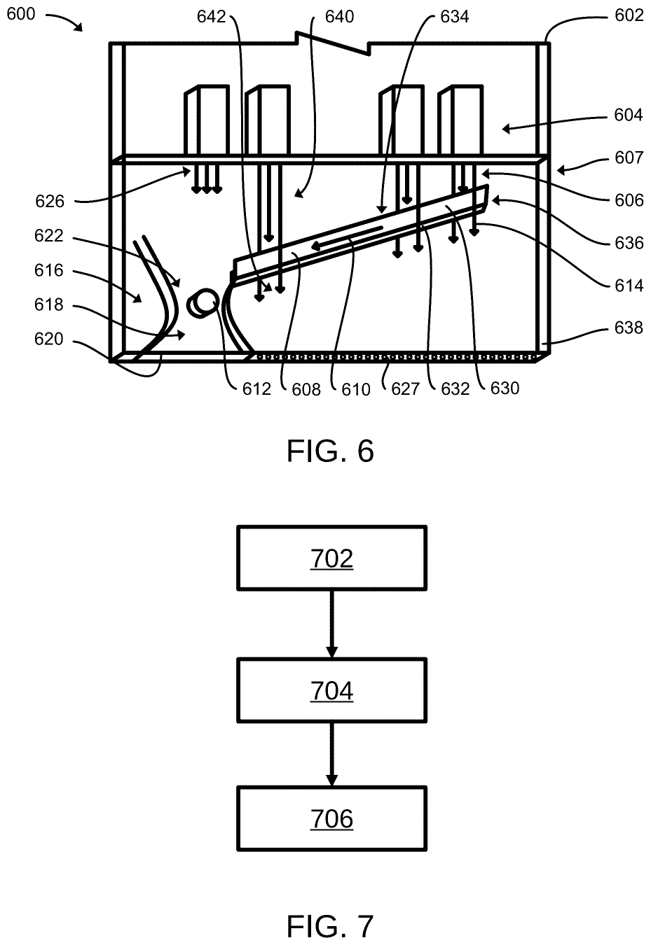

Referring now to FIG. 2, therein is shown an inverted cone 202 for use with an embodiment of the sampling system. Illustratively, for example, the inverted cone 202 can be the inverted cone 116 of FIG. 1, the inverted cone 416 of FIG. 4, the inverted cone 516 of FIG. 5, or the inverted cone 616 of FIG. 6.

The inverted cone 202 is shown producing a low pressure region 204 near a bottom 206 of the inverted cone 202. A top 208 of the inverted cone 202 can be coupled to a single angled channel 210 in order to direct samples of air, smoke, aerosols, and suspended particles along the angled channel 210 and into the inverted cone 202.

The inverted cone 202 can be positioned near a cooling fan and downstream to the angled channel 210. It is contemplated that the inverted cone 202 could be positioned upstream or downstream to the cooling fan.

The inverted cone 202 is shown with the bottom 206 being wider than the top 208. The inverted cone 202 can extend from the top 208 to the bottom 206 with a concave curve 214. The inverted cone 202 can transition from the concave curve 214 to a convex curve 216 near the bottom 206.

The inverted cone 202 is further shown with an optional top enclosure 218. The top enclosure 218 can be an enclosed or enclosing bend that can prevent air from entering the inverted cone 202 from upwind air directly above the inverted cone 202. Rather the samples must enter the inverted cone 202 through an open top 220 of the angled channel 210.

The top enclosure 218 increases air velocity at the output of the angled channel 210. As will be appreciated, the inverted cone 202 could be connected to multiple angled channels.

Referring now to FIG. 3, therein is shown a left side isometric view of the sampling system 300 in a second embodiment. The sampling system 300 can comprise a substrate 302 which can be mounted within a vented enclosure as described with regard to FIG. 1, for example. For descriptive clarity, the vented enclosure is not shown.

The substrate 302 can for example be a printed circuit board. Multiple air columns 306 can be created by powerful cooling fans within the vented enclosure. Extending across the air columns 306 and across the substrate 302, angled channels 308 are depicted.

The angled channels 308 are a mechanical apparatus that can re-direct samples 310 of air from within the air columns 306, and across the air columns 306, to a detector 312. The samples 310 can also be pulled into the angled channels 308 from air outside the more quickly moving air columns 306.

The detector 312 can be any type of sensor including a smoke detector, a gas detector, an aerosol detector, or other detector for suspended particles. It has been discovered that mounting the angled channel 308 on a surface of the substrate 302 does not impact the overall cooling efficiency of the vented enclosure within which it is placed. One reason for this is that the angled channel 308 collects the sample 310 but also allows other air from the air columns 306 to bypass the angled channel 308.

This bypass air 314 continues with little interruption within the air column 306. Since the bypass air 314 is minimally impeded, redirected, or otherwise changed, the cooling efficiency remains outstanding. The cross-sectional size of the angled channels 308 is a small fraction in relation to the cross-sectional size of the air column 306 and the height of the substrate vented enclosure so as to minimize the overall impact to airflow within the case.

The bypass air 314 is shown bypassing the angled channels 308 on one side while the sample 310 is collected from the air column 306 near the substrate 302. Notably, the angled channels 308 can extend across all the air columns 306 and across an entire width of the substrate 302 allowing the samples 310 to be collected from the entire width of the substrate 302. Alternatively, as is shown, the angled channels 308 can extend near an edge of the substrate 302 while still leaving some of the substrate 302 exposed.

The angled channels 308 can include a channel sidewall 330, a channel bottom 332, a channel open top 334, and a channel open end 336. The channel sidewall 330 is depicted as a single wall extending from the channel bottom 332 to terminate in the channel open top 334.

As shown, the angled channels 308 can have a squared off cross-sectional shape with the channel bottom 332 being the same width as the channel open top 334; however, it is also contemplated that the channel sidewall 330 could be slanted with the channel bottom 332 being narrower than the channel open top 334. The channel open end 336 can terminate near an edge 338 of the substrate 302 while the other end of the angled channels 308 can terminate near the detector 312.

The angled channels 308 can be mounted to the substrate 302 with attachment extensions 340. The attachment extensions 340 are shown to extend from the channel bottom 332 away from the channel open top 334, however some contemplated embodiments can include the attachment extensions 340 extending from the channel bottom 332 toward the channel open top 334.

The angled channels 308 can be slanted or angled down toward the detector 312 and can direct the samples 310 to the detector 312. The moving air within the air columns 306 can create air that is upwind 342 being closer to enclosure input ports and air that is downwind 344 being closer to enclosure exit ports. The channel open top 334 can face upwind 342. Furthermore, the channel open end 336 can be further upwind 342 relative to the end of the angled channel 308 near the detector 312.

Referring now to FIG. 4, therein is shown a front isometric view of the sampling system 400 in a third embodiment. The sampling system 400 is shown having a vented enclosure 402.

The vented enclosure 402 can be a fan vented server including cooling fans 404. The cooling fans 404 can be powerful, high-velocity fans which create isolated air columns 406 within the vented enclosure 402.

Angled channels 408 are depicted extending width-wise within the vented enclosure 402. A first angled channel 409 can extend across multiple air columns 406 and can re-direct samples 410 of air from within the air columns 406, and across the air columns 406, to a detector 412.

The samples 410 can also be pulled into a second angled channel 413 or the first angled channel 409 from air outside the more quickly moving air columns 406. The second angled channel 413 can extend into the vented enclosure 402 without crossing any of the air columns 406.

The detector 412 can be any type of sensor including a smoke detector, a gas detector, an aerosol detector, or other detector for suspended particles. Illustratively for example, the detector 412 can detect smoke from the combustion of a computing component within the vented enclosure 402 or could detect aerosols of vaporized capacitors from within the vented enclosure 402.

It has been discovered that implementing the angled channel 408 within the vented enclosure 402 does not impact the overall cooling efficiency of the vented enclosure 402. One reason for this is that the angled channel 408 collects the sample 410 but also allows other air from the air columns 406 to bypass the angled channel 408.

This bypass air 414 continues with little interruption within the air column 406. Since the bypass air 414 is minimally impeded, redirected, or otherwise changed, the cooling efficiency remains outstanding. The cross-sectional size of the angled channels 408 is a small fraction in relation to the cross-sectional size of the air column 406 and the height of the vented enclosure 402 so as to minimize the overall impact to airflow within the case.

The bypass air 414 is shown bypassing the angled channels 408 on two sides while the sample 410 is collected from the middle. Notably, the first angled channel 409 can extend across three of the air columns 406. The first angled channel 409 and the second angled channel 413, together, can extend across an entire width of the vented enclosure 402 allowing the samples 410 to be collected from the entire width of the vented enclosure 402.

The samples 410 can be redirected to the detector 412 within an inverted cone 416. The inverted cone 416 produces a low pressure region 418 within the inverted cone 416 itself and near a bottom 420 of the inverted cone 416. The inverted cone 416 also produces high velocity air near a top 422 of the inverted cone 416 which pulls air, smoke, aerosols, and suspended particles along the angled channels 408 and into the inverted cone 416.

Connecting the inverted cone 416 to the angled channels 408 therefore provides a high velocity intake along the angled channels 408. It has been discovered that the inverted cone 416 can increase the velocity of air within the angled channels 408 so that there is no pressure build up and airflow can be maintained within the vented enclosure 402 without degrading cooling efficiency.

The vented enclosure 402 can include enclosure input ports 424 all along one side of the vented enclosure 402 and enclosure exit ports 426 with the air columns 406 flowing therebetween. The air columns 406 do not generally mix within the vented enclosure 402 but rather flow in a direct path from the enclosure input ports 424 to the enclosure exit ports 426.

It is contemplated that the enclosure input ports 424 could be a mesh, a screen, or an open end of the vented enclosure 402. Each of the cooling fans 404 can include a fan intake 428 where the air columns 406 are pulled into the cooling fans 404. The cooling fans 404 can terminate at the enclosure exit ports 426 where the cooling fans 404 exhaust the air columns 406 at speeds that can reach up to sixty kilometers per hour.

The angled channels 408 can include channel sidewalls 430, a channel bottom 432, a channel open top 434, and a channel open end 436. The channel sidewalls 430 are depicted as two walls extending from the channel bottom 432 to terminate in the channel open top 434.

As shown, the angled channels 408 can have a square or rectangular cross-sectional shape with the channel bottom 432 being the same width as the channel open top 434; however, it is also contemplated that the channel sidewalls 430 could be slanted with the channel bottom 432 being narrower than the channel open top 434. The channel open end 436 can terminate in contact with enclosure walls 438 of the vented enclosure 402 while the other end of the angled channels 408 can terminate at the inverted cone 416.

The top 422 of the inverted cone 416 can be narrow in relation to the larger bottom 420 in order to create the low pressure region 418 near the bottom 420 of the inverted cone 416. The angled channels 408 can terminate at the top 422 of the inverted cone 416 with the channel sidewalls 430 and channel bottom 432 in direct contact with the inverted cone 416.

The top 422 of the inverted cone 416 can also be open similar to the channel open top 434. The inverted cone 416 can be positioned within one of the air columns 406 and can accept the samples 410 directly from the air column 406 through the top 422. The angled channels 408 can be slanted or angled down toward the detector 412.

The moving air within the air columns 406 can create air that is upwind 440 being closer to the enclosure input ports 424 and air that is downwind 442 being closer to the enclosure exit ports 426.

The channel open top 434 can face upwind 440. Furthermore, the channel open end 436 can be further upwind 440 relative to the end of the angled channel 408 coupled to the inverted cone 416. The inverted cone 416 is depicted downwind 442 to the angled channels 408.

Referring now to FIG. 5, therein is shown a front isometric view of the sampling system 500 in a fourth embodiment. The sampling system 500 is shown having a vented enclosure 502.

The vented enclosure 502 can be a fan vented server including cooling fans 504. The cooling fans 504 can be powerful, high-velocity fans which create isolated air columns 506 within the vented enclosure 502.

Extending across multiple air columns 506 within the vented enclosure 502, angled channels 508 are depicted. The angled channels 508 are a mechanical apparatus that can re-direct samples of air from within the air columns 506, and across the air columns 506, to detectors 512. The samples can also be pulled into the angled channels 508 from air outside the more quickly moving air columns 506.

The detectors 512 can be any type of sensor including smoke detectors, gas detectors, aerosol detectors, other detector for suspended particles, or a combination thereof. As depicted, the detectors 512 comprise two individual detectors into which the angled channels 508 can direct the samples.

While more detectors 512 are used, the number of detectors 512 is still less than the number of the air columns 506 and therefore still reduces costs to an acceptable level for widespread industry adoption. The detectors 512 can detect smoke from the combustion of a computing component within the vented enclosure 502 or could detect aerosols of vaporized capacitors from within the vented enclosure 502.

It has been discovered that implementing the angled channel 508 within the vented enclosure 502 does not impact the overall cooling efficiency of the vented enclosure 502. One reason for this is that the angled channel 508 collects the sample but also allows other air from the air columns 506 to bypass the angled channel 508.

The bypass air can bypass the angled channels 508 on two sides and can also pass through spaces 513 in a channel bottom 514. The channel bottom 514 being offset in steps. The samples collected by the angled channels 508 having the spaces 513 therein, can be less than when using the angled channel 108 of FIG. 1, for example, but could still provide enough air to detect combustion or aerosol events.

This bypass air continues with little interruption within the air column 506. Since the bypass air is minimally impeded, redirected, or otherwise changed, the cooling efficiency remains outstanding. The cross-sectional size of the angled channels 508 is a small fraction in relation to the cross-sectional size of the air column 506 and the height of the vented enclosure 502 so as to minimize the overall impact to airflow within the case.

The samples can be redirected to the detectors 512 positioned below an inverted cone 516. The detectors 512 can be positioned between the inverted cone 516 and the cooling fans 504.

The inverted cone 516 can have a narrower top in relation to a larger bottom in order to create a low pressure region 518 near the bottom of the inverted cone 516. The detectors 512 are positioned within the low pressure region 518.

The vented enclosure 502 can include enclosure input ports 524 all along one side of the vented enclosure 502 and enclosure exit ports 526 with the air columns 506 flowing therebetween. The air columns 506 do not generally mix within the vented enclosure 502 but rather flow in a direct path from the enclosure input ports 524 to the enclosure exit ports 526.

It is contemplated that the enclosure input ports 524 could be a mesh, a screen, or an open end of the vented enclosure 502. Each of the cooling fans 504 can include a fan intake 528 where the air columns 506 are pulled into the cooling fans 504.

The cooling fans 504 can terminate at the enclosure exit ports 526 where the cooling fans 504 exhaust the air columns 506 at speeds that can reach up to sixty kilometers per hour. The moving air within the air columns 506 can create air that is upwind 540 being closer to the enclosure input ports 524 and air that is downwind 542 being closer to the enclosure exit ports 526.

Referring now to FIG. 6, therein is shown a front isometric view of the sampling system 600 in a fifth embodiment. The sampling system 600 is shown having a vented enclosure 602.

The vented enclosure 602 can be a fan vented server including cooling fans 604. The cooling fans 604 can be powerful, high-velocity fans which create isolated air columns 606 within the vented enclosure 602 and which flow out of the vented enclosure 602.

The air columns 606 flowing out of the vented enclosure 602 can be monitored by an exhaust attachment 607 coupled to the exhaust ports of the vented enclosure 602. The exhaust attachment 607 can be the same width and height as the vented enclosure.

The cooling fans 604 can force the air columns 606 through the exhaust attachment 607. Extending across multiple air columns 606 within the exhaust attachment 607, an angled channel 608 is depicted. The angled channel 608 is a mechanical apparatus that can re-direct samples 610 of air from within the air columns 606, and across the air columns 606, to a detector 612. The samples 610 can also be pulled into the angled channel 608 from air outside the more quickly moving air columns 606.

The detector 612 can be any type of sensor including a smoke detector, a gas detector, an aerosol detector, or other detector for suspended particles. Illustratively for example, the detector 612 can detect smoke from the combustion of a computing component within the vented enclosure 602 or could detect aerosols of vaporized capacitors from within the vented enclosure 602.

It has been discovered that implementing the angled channel 608 within the exhaust attachment 607 provides a retrofitting option for older model servers. This provides an ultra-low cost implementation option that previous solutions did not provide.

Furthermore, implementing the angled channel 608 within the exhaust attachment 607 does not impact the overall cooling efficiency of the vented enclosure 602. One reason for this is that the angled channel 608 collects the sample 610 but also allows other air from the air columns 606 to bypass the angled channel 608.

This bypass air 614 continues with little interruption within the air column 606. Since the bypass air 614 is minimally impeded, redirected, or otherwise changed, the cooling efficiency remains outstanding. The cross-sectional size of the angled channel 608 is a small fraction in relation to the cross-sectional size of the air column 606 and the height of the exhaust attachment 607 so as to minimize the overall impact to airflow within the case.

The bypass air 614 is shown bypassing the angled channel 608 on two sides while the sample 610 is collected from the middle. Notably, the angled channel 608 can extend across multiple air columns 606.

The samples 610 can be redirected to the detector 612 through an inverted cone 616. The inverted cone 616 produces a low pressure region 618 within the inverted cone 616 and near a bottom 620 of the inverted cone 616. The inverted cone 616 also produces high velocity air near a top 622 which pulls air, smoke, aerosols, and suspended particles along the angled channel 608 and into the inverted cone 616.

A cone extension 623 can extend up from the top 622 of the inverted cone 616. The cone extension 623 can direct samples to the detector 612. The cone extension 623 together with the inverted cone 616 and the angled channel 608 can extend across all air columns 606 of the vented enclosure 602.

Connecting the inverted cone 616 to the angled channel 608 therefore provides a high velocity intake along the angled channel 608. It has been discovered that the inverted cone 616 can increase the velocity of air within the angled channel 608 so that there is no pressure build up and airflow can be maintained within the exhaust attachment 607 without degrading cooling efficiency.

The detector 612 can be positioned within the low pressure region 618, which can be within the inverted cone 616. The vented enclosure 602 can also include enclosure exit ports 626. The air columns 606 do not generally mix within the vented enclosure 602 or within the exhaust attachment 607 but rather flow in a direct path from enclosure input ports to the enclosure exit ports 626 and through the exhaust attachment 607 to an exhaust port 627 of the exhaust attachment 607.

The input of the exhaust attachment 607 is shown to be the exit ports 626 of the vented enclosure 602. It is contemplated that each of the cooling fans 604 will correspond with one of the enclosure exit ports 626 and to one of the air columns 606. The cooling fans 604 can terminate at the enclosure exit ports 626 where the cooling fans 604 exhaust the air columns 606 at speeds that can reach up to sixty kilometers per hour through the exhaust attachment 607.

The angled channel 608 can include channel sidewalls 630, a channel bottom 632, a channel open top 634, and a channel open end 636. The channel sidewalls 630 are depicted as two walls extending from the channel bottom 632 to terminate in the channel open top 634.

As shown, the angled channel 608 can have a squared off cross-sectional shape with the channel bottom 632 being the same width as the channel open top 634; however, it is also contemplated that the channel sidewalls 630 could be slanted with the channel bottom 632 being narrower than the channel open top 634. The channel open end 636 can terminate near an enclosure wall 638 of the exhaust attachment 607 while the other end of the angled channel 608 can terminate at the inverted cone 616.

The top 622 of the inverted cone 616 can be narrow in relation to the larger bottom 620 in order to create the low pressure region 618 near the bottom 620 of the inverted cone 616. The angled channel 608 can terminate at the top 622 of the inverted cone 616 with the channel sidewalls 630 and channel bottom 632 in direct contact with the inverted cone 616.

The top 622 of the inverted cone 616 can also be open similar to the channel open top 634 and can accept the samples 610 directly from the air column 606 through the top 622. The angled channel 608 can be slanted or angled down toward the detector 612.

The moving air within the air columns 606 can create air that is upwind 640 being closer to the exit ports 626 of the vented enclosure 602 and air that is downwind 642 being closer to the exhaust ports 627 of the exhaust attachment 607.

The channel open top 634 can face upwind 640. Furthermore, the channel open end 636 can be further upwind 640 relative to the end of the angled channel 608 coupled to the inverted cone 616. The inverted cone 616 is depicted downwind 642 to the angled channel 608.

Referring now to FIG. 7, therein is shown a method of manufacturing the sampling system. The method can include providing a fan vented enclosure with cooling fans for creating air columns, each of the air columns corresponding to one of the cooling fans in a block 702; coupling a detector to the fan vented enclosure in a block 704; and coupling an angled channel to the fan vented enclosure, the angled channel configured to redirect a sample across at least one of the air columns to the detector such that a number of detectors is less than a number of air columns, the angled channel further configured to allow bypass air to flow around the angled channel in a block 706.

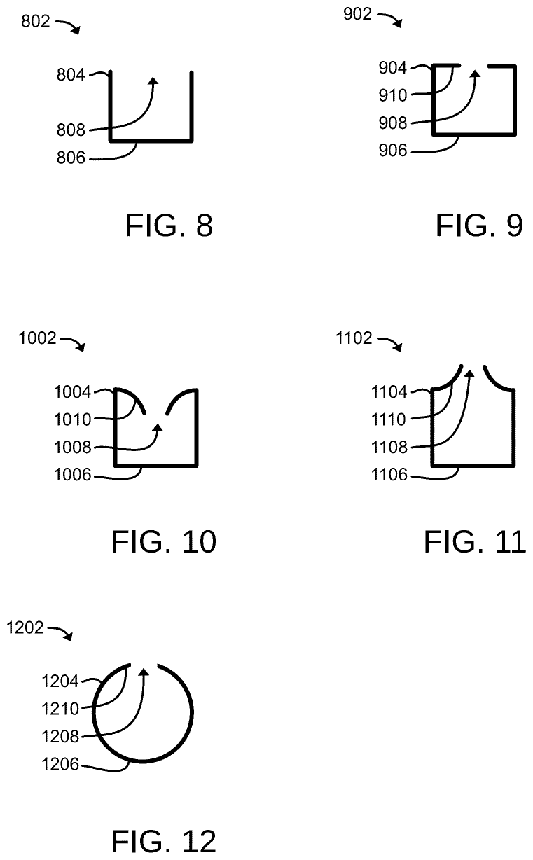

Referring now to FIG. 8, therein is shown a cross-sectional view of the angled channel 802 in a second embodiment. The angled channel 802 is depicted with a rectangular cross-sectional shape with a fully open top. The angled channel 802 can include channel sidewalls 804, a channel bottom 806, and a channel open top 808.

The channel sidewalls 804 are depicted as two substantially vertically extending portions of a circle extending upwind from the channel bottom 806 to terminate at the channel open top 808. Channel overhangs are not used to create the channel open top 808, rather the channel side walls 804 form the channel open top 808 upwind of the channel bottom 806.

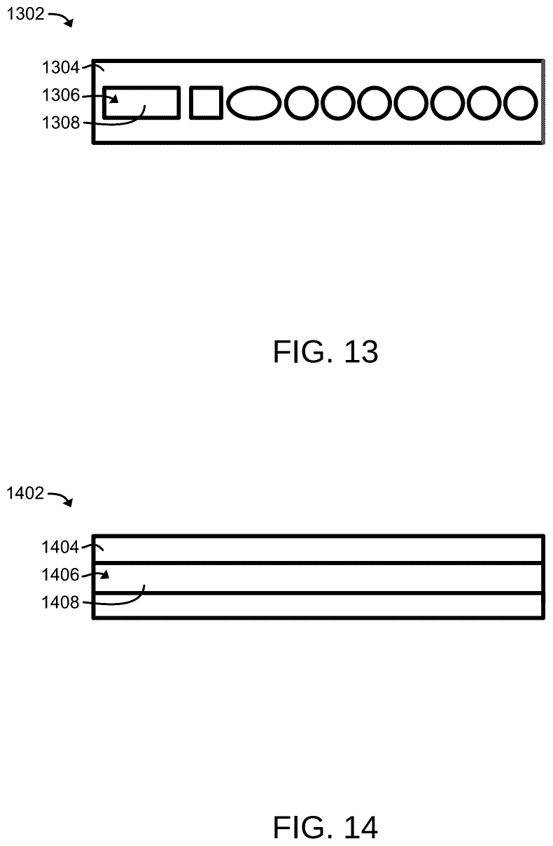

The channel open top 808 can be an opening of various shapes and in various patterns as shown for example in FIGS. 13 and 14. Illustratively, for example the channel open top 808 can be a hole, a series of hole, or a slot.

Referring now to FIG. 9, therein is shown a cross-sectional view of the angled channel 902 in a third embodiment. The angled channel 902 is depicted with a rectangular cross-sectional shape. The angled channel 902 can include channel sidewalls 904, a channel bottom 906, a channel open top 908, and channel overhangs 910.

The channel sidewalls 904 are depicted as two walls extending upwind from the channel bottom 906 to terminate at the channel overhangs 910. The channels overhangs 910 forming the channel open top 908 upwind of the channel bottom 906.

The channel overhang 910 can extend laterally over and substantially co-planar with the channel bottom 906 in order to create the channel open top 908, which can be an opening of various shapes and in various patterns as shown for example in FIGS. 13 and 14. Illustratively, for example the channel open top 908 can be a hole, a series of hole, or a slot.

The channel overhang 910 and the channel sidewalls 904 can have a squared off flat shape when forming the channel open top 908. It has been unexpectedly discovered that the squared off flat shape provides an upwind restriction or shape that aids in retention of the smoke flow in the channel and helps to prevent strong airflow from flushing smoke, aerosols, and suspended particulates out of the angled channel 902 that were acquired by the angled channel 902 upstream.

Referring now to FIG. 10, therein is shown a cross-sectional view of the angled channel 1002 in a fourth embodiment. The angled channel 1002 is depicted with a rectangular cross-sectional shape with an inward extending top. The angled channel 1002 can include channel sidewalls 1004, a channel bottom 1006, a channel open top 1008, and channel overhangs 1010.

The channel sidewalls 1004 are depicted as two walls extending upwind from the channel bottom 1006 to terminate at the channel overhangs 1010. The channels overhangs 1010 forming the channel open top 1008 upwind of the channel bottom 1006.

The channel overhang 1010 can extend laterally over and extend down in a curve from the channel sidewalls 1004 toward the channel bottom 1006 in order to create the channel open top 1008, which can be an opening of various shapes and in various patterns as shown for example in FIGS. 13 and 14. Illustratively, for example the channel open top 1008 can be a slot.

The channel overhang 1010 can have a curved shape when forming the channel open top 1008. It has been unexpectedly discovered that the squared off flat shape provides an upwind restriction or shape that aids in retention of the smoke flow in the channel and helps to prevent strong airflow from flushing smoke, aerosols, and suspended particulates out of the angled channel 1002 that were acquired by the angled channel upstream.

Referring now to FIG. 11, therein is shown a cross-sectional view of the angled channel 1102 in a fifth embodiment. The angled channel 1102 is depicted with a rectangular bottle cross-sectional shape with an upward extending top. The angled channel 1102 can include channel sidewalls 1104, a channel bottom 1106, a channel open top 1108, and channel overhangs 1110.

The channel sidewalls 1104 are depicted as two walls extending upwind from the channel bottom 1106 to terminate at the channel overhangs 1110. The channels overhangs 1110 forming the channel open top 1108 upwind of the channel bottom 1106.

The channel overhang 1110 can extend laterally over and extend upward in a curve from the channel sidewalls 1104 away from the channel bottom 1106 in order to create the channel open top 1108, which can be an opening of various shapes and in various patterns as shown for example in FIGS. 13 and 14. Illustratively, for example the channel open top 1108 can be a slot.

The channel overhang 1110 can have a curved shape when forming the channel open top 1108. It has been unexpectedly discovered that the squared off flat shape provides an upwind restriction or shape that aids in retention of the smoke flow in the channel and helps to prevent strong airflow from flushing smoke, aerosols, and suspended particulates out of the angled channel 1102 that were acquired by the angled channel upstream.

Referring now to FIG. 12, therein is shown a cross-sectional view of the angled channel 1202 in a sixth embodiment. The angled channel 1202 is depicted with a circular cross-sectional shape with an upward extending top. The angled channel 1202 can include channel sidewalls 1204, a channel bottom 1206, a channel open top 1208, and channel overhangs 1210.

The channel sidewalls 1204 are depicted as two substantially vertically extending portions of a circle extending upwind from the channel bottom 1206 to terminate at the channel overhangs 1210. The channels overhangs 1210 forming the channel open top 1208 upwind of the channel bottom 1206.

The channel overhang 1210 can extend laterally over and extend upward in a curve from the channel sidewalls 1204 away from the channel bottom 1206 in order to create the channel open top 1208, which can be an opening of various shapes and in various patterns as shown for example in FIGS. 13 and 14. Illustratively, for example the channel open top 1208 can be a hole, a series of hole, or a slot.

The channel overhang 1210 can have a curved shape when forming the channel open top 1208. It has been unexpectedly discovered that the squared off flat shape provides an upwind restriction or shape that aids in retention of the smoke flow in the channel and helps to prevent strong airflow from flushing smoke, aerosols, and suspended particulates out of the angled channel 1202 that were acquired by the angled channel upstream.

Referring now to FIG. 13, therein is shown a top view of the angled channel 1302 for implementation with an embodiment of the angled channel. The angled channel 1302 is shown with channel overhangs 1304 forming a channel open top 1306 in the shape of a hole or series of holes upwind from a channel bottom 1308. For example, the channel open top 1306 can be a rectangular hole, a series of rectangular holes, a series of square holes, a series of circular holes, or a series of elliptical holes.

Referring now to FIG. 14, therein is shown a top view of the angled channel 1402 for implementation with an embodiment of the angled channel. The angled channel 1402 is shown with channel overhangs 1404 forming a channel open top 1406 in the shape of a slot upwind from a channel bottom 1408.

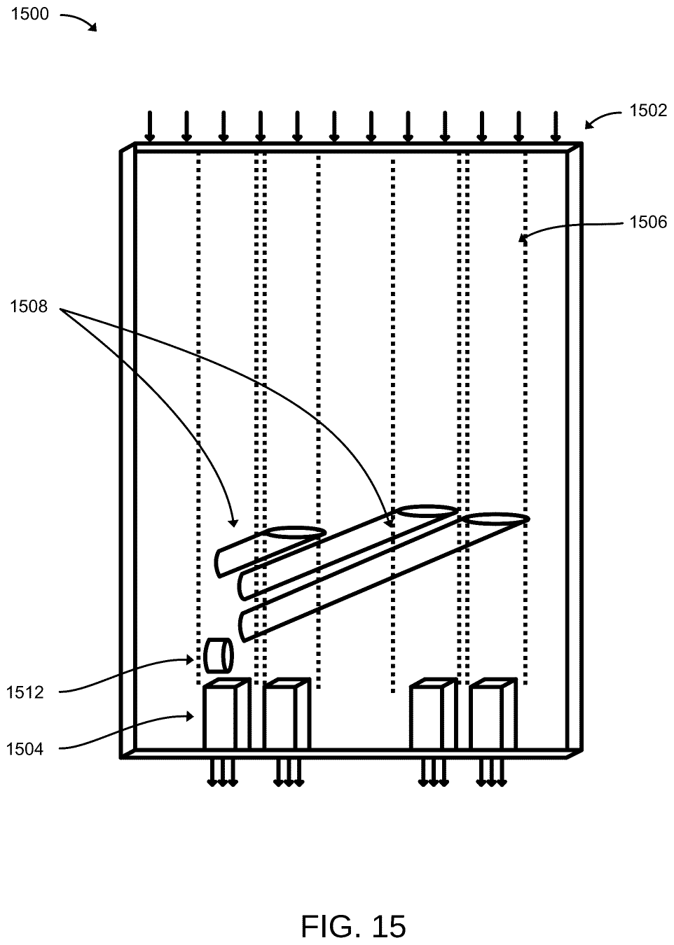

Referring now to FIG. 15, therein is shown a front isometric view of the sampling system 1500 in a sixth embodiment. The sampling system 1500 is shown having a vented enclosure 1502.

The vented enclosure 1502 can be a fan vented server including cooling fans 1504. The cooling fans 1504 can be powerful, high-velocity fans which create isolated air columns 1506 within the vented enclosure 1502.

Extending across multiple air columns 1506 within the vented enclosure 1502, angled channels 1508 are depicted. The angled channels 1508 are a mechanical apparatus that can re-direct samples of air from within the air columns 1506, and across the air columns 1506, to detectors 1512. The present embodiment depicts the angled channels 1508 in the form of tubes with angled open ends. The tubes are not necessarily drawn to scale, but there is shown separate sample angled channels 1508 for each air stream. The angled channels 1508 then dump into a single air column 156 where the detector 1512 is located.

The angled channels 1508 can terminate within the air column 1508 having the detector 1512. It has been discovered that the angled channels 1508 arranged as tubes has some advantages because the samples from one air column can interfere with the samples from another air column when collected in a single angled channel.

It has been discovered that implementing the angled channel 1508 within the vented enclosure 1502 does not impact the overall cooling efficiency of the vented enclosure 1502. One reason for this is that the angled channel 1508 collects the sample but also allows other air from the air columns 1506 to bypass the angled channel 1508.

This bypass air continues with little interruption within the air column 1506. Since the bypass air is minimally impeded, redirected, or otherwise changed, the cooling efficiency remains outstanding. The cross-sectional size of the angled channels 1508 is a small fraction in relation to the cross-sectional size of the air column 1506 and the height of the vented enclosure 1502 so as to minimize the overall impact to airflow within the case.

The bypass air is shown bypassing the angled channels 1508 on two sides while the sample is collected from the middle. Notably, the angled channels 1508 can extend across some or all the air columns 1506 and across an entire width of the vented enclosure 1502 allowing the samples to be collected from the entire width of the vented enclosure 1502.

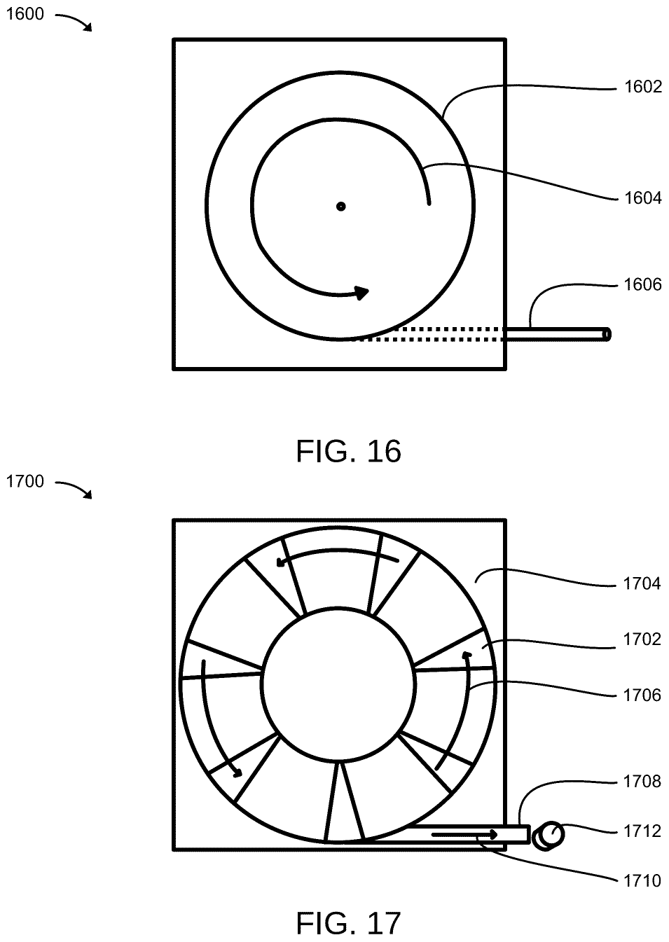

Referring now to FIG. 16, therein is shown a top cross-sectional view of the sampling system 1600 in a seventh embodiment. The sampling system 1600 is shown with only the cooling fan in a cross-sectional view having a fan cowling 1602. The fan blade is not shown.

The arrow 1604 indicates the direction of rotation of the fan. There is shown a tube tap 1606 off from the side of the fan cowling 1602. The tube is then run to a single detector, not shown.

Referring now to FIG. 17, therein is shown a top cross-sectional view of the sampling system 1700 in an eighth embodiment. The sampling system 1700 is shown with only a cooling fan 1702 surrounded by a fan cowling 1704.

The arrow 1706 indicates the direction of rotation of the fan. There is shown a centripetal tube tap 1708 off from the side of the fan cowling 1704. The centripetal tube tap 1708 can direct a sample of air 1710 to a detector 1712.

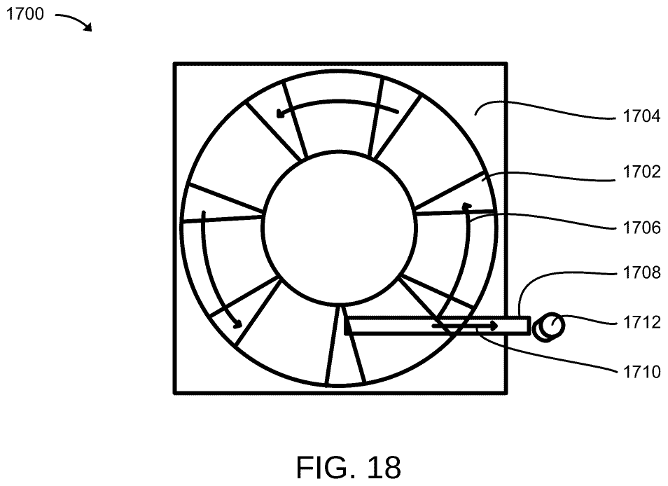

Referring now to FIG. 18, therein is shown a top cross-sectional view of the sampling system 1800 in a ninth embodiment. The sampling system 1800 is shown with only a cooling fan 1802 surrounded by a fan cowling 1804.

The arrow 1806 indicates the direction of rotation of the fan. There is shown a tube tap 1808 off from the side of the fan cowling 1804. The tube tap 1808 can direct a sample of air 1810 to a detector 1812. It is contemplated that the tube tap 1808 can be placed at any location where the sample of air 1810 is desired or likely to detect air containing samples detectable by the detector 1812.

Thus, it has been discovered that the sampling system furnishes important and heretofore unknown and unavailable solutions, capabilities, and functional aspects. The resulting configurations are straightforward, cost-effective, uncomplicated, highly versatile, do not impact cooling efficiency, and effective, and can be implemented by adapting known components for ready, efficient, and economical manufacturing, application, and utilization.

While the sampling system has been described in conjunction with a specific best mode, it is to be understood that many alternatives, modifications, and variations will be apparent to those skilled in the art in light of the preceding description. Accordingly, it is intended to embrace all such alternatives, modifications, and variations, which fall within the scope of the included claims. All matters set forth herein or shown in the accompanying drawings are to be interpreted in an illustrative and non-limiting sense.

What is claimed is:

1. A fan vented enclosure sampling system comprising:
a detector; and
an angled channel coupled to the detector, the detector and the angled channel configured to be coupled to a fan vented enclosure, the angled channel configured to redirect a sample from air columns to the detector such that a number of detectors is less than a number of air columns, and the angled channel further configured to allow bypass air to flow around the angled channel.

2. The system of claim 1 further comprising: an inverted cone coupled to the angled channel, the inverted cone configured to provide a low pressure region where the detector is positioned.

3. The system of claim 1 wherein: the angled channel is configured to couple to the fan vented enclosure downwind of an exit port of the fan vented enclosure.

4. The system of claim 1 wherein: the detector and the angled channel are configured to mount within the fan vented enclosure.

5. The system of claim 1 wherein: the detector is configured to detect smoke, an aerosol, a suspended particle, or a gas.

6. The system of claim 1 wherein: the angled channel comprises a channel sidewall, a channel bottom, a channel open top, and a channel overhang, the channel sidewall configured to extend upwind from the channel bottom and to terminate at the channel overhang, the channel overhang forming the channel open top, the channel overhang extends over the channel bottom and extends in a curve from the channel sidewall away from the channel bottom to create the channel open top.

7. The system of claim 1 wherein: the angled channel comprises a channel sidewall, a channel bottom, a channel open top, and a channel overhang, the channel sidewall configured to extend upwind from the channel bottom and to terminate at the channel overhang, the channel overhang forming the channel open top, the channel overhang extends over the channel bottom and extends in a curve from the channel sidewall toward the channel bottom to create the channel open top.

8. The system of claim 1 wherein: the angled channel comprises a channel sidewall, a channel bottom, a channel open top, and a channel overhang, the channel sidewall configured to extend upwind from the channel bottom and to terminate at the channel overhang, the channel overhang forming the channel open top, the channel overhang extends from the channel sidewall over the channel bottom to create the channel open top.

9. The system of claim 1 wherein: the angled channel has a rectangular cross-sectional shape.

10. The system of claim 1 wherein: the angled channel has a rounded cross-sectional shape.

11. The system of claim 1 wherein: the angled channel is a tube.

12. A fan vented enclosure sampling system comprising:
a fan vented enclosure with cooling fans for creating air columns, each of the air columns corresponding to one of the cooling fans;
a detector coupled to the fan vented enclosure; and
an angled channel coupled to the fan vented enclosure, the angled channel configured to redirect a sample across at least one of the air columns to the detector such that a number of detectors is less than a number of air columns, the angled channel further configured to allow bypass air to flow around the angled channel.

13. The system of claim 12 further comprising: a printed circuit board, and wherein the angled channel is mounted in direct contact with the printed circuit board.

14. The system of claim 12 further comprising: an inverted cone coupled to the angled channel, the inverted cone including a top enclosure configured to isolate the sample of the angled channel from the air columns.

15. The system of claim 12 wherein: the angled channel includes a channel bottom configured as a step and configured to allow the bypass air to flow through a space in the channel bottom.

16. The system of claim 12 wherein: the angled channel includes an open top configured to be upwind to a channel bottom.

17. A method of manufacturing a fan vented sampling system comprising:
providing a detector; and
coupling an angled channel to the detector, the detector and the angled channel configured to be coupled to a fan vented enclosure, the angled channel configured to redirect a sample from air columns to the detector such that a number of detectors is less than a number of air columns, and the angled channel further configured to allow bypass air to flow around the angled channel.

18. The method of claim 17 further comprising: coupling an inverted cone to the angled channel, the inverted cone configured to provide a low pressure region where the detector is positioned.

19. The method of claim 17 wherein: coupling the angled channel includes coupling the angled channel downwind of an exit port of the fan vented enclosure.

20. The method of claim 17 wherein: coupling the angled channel includes mounting the angled channel within the fan vented enclosure.

21. The method of claim 17 wherein: providing the detector includes providing the detector configured to detect smoke, an aerosol, a suspended particle, or a gas.

22. The method of claim 17 wherein: coupling the angled channel includes coupling the angled channel comprising a channel sidewall, a channel bottom, a channel open top, and a channel overhang, the channel sidewall configured to extend upwind from the channel bottom and to terminate at the channel overhang, the channel overhang forming the channel open top, the channel overhang extends over the channel bottom and extends in a curve from the channel sidewall away from the channel bottom to create the channel open top.

23. The method of claim 17 wherein: coupling the angled channel includes coupling the angled channel comprising a channel sidewall, a channel bottom, a channel open top, and a channel overhang, the channel sidewall configured to extend upwind from the channel bottom and to terminate at the channel overhang, the channel overhang forming the channel open top, the channel overhang extends over the channel bottom and extends in a curve from the channel sidewall toward the channel bottom to create the channel open top.

24. The method of claim 17 wherein: coupling the angled channel includes coupling the angled channel comprising a channel sidewall, a channel bottom, a channel open top, and a channel overhang, the channel sidewall configured to extend upwind from the channel bottom and to terminate at the channel overhang, the channel overhang forming the channel open top, the channel overhang extends from the channel sidewall over the channel bottom to create the channel open top.

25. The method of claim 17 wherein: coupling the angled channel includes coupling the angled channel comprising a rectangular cross-sectional shape.

26. The method of claim 17 wherein: coupling the angled channel includes coupling the angled channel comprising a rounded cross-sectional shape.

27. The method of claim 17 wherein: coupling the angled channel includes coupling the angled channel in the form of a tube.

28. The method of claim 17 wherein: coupling the angled channel includes coupling the angled channel to the fan vented enclosure having cooling fans for creating the air columns, each of the air columns corresponding to one of the cooling fans, and the angled channel configured to redirect the sample across at least one of the air columns.

29. The method of claim 28 further comprising: mounting the angled channel in direct contact with a printed circuit board.

30. The method of claim 28 further comprising: coupling an inverted cone to the angled channel, the inverted cone including a top enclosure configured to isolate the sample of the angled channel from the air columns.

31. The method of claim 28 wherein: coupling the angled channel includes coupling the angled channel having a channel bottom configured as a step and configured to allow the bypass air to flow through a space in the channel bottom.

32. The method of claim 28 wherein: coupling the angled channel includes coupling the angled channel having an open top configured to be upwind to a channel bottom.

33. A fan vented enclosure sampling system comprising:
a fan vented enclosure;
a detector coupled to the fan vented enclosure;
a first fan coupled to the fan vented enclosure, the first fan including a first cowling, the first cowling including a first tube tap from a first side of the first cowling; and
a second fan coupled to the fan vented enclosure, the second fan including a second cowling, the second cowling including a second tube tap from a second side of the second cowling, the first tube tap and the second tube tap extending to the detector.

34. A method of manufacturing a fan vented enclosure sampling system comprising:
providing a fan vented enclosure;
coupling a detector to the fan vented enclosure;
coupling a first fan to the fan vented enclosure, the first fan including a first cowling, the first cowling including a first tube tap from a first side of the first cowling; and
coupling a second fan to the fan vented enclosure, the second fan including a second cowling, the second cowling including a second tube tap from a second side of the second cowling, the first tube tap and the second tube tap extending to the detector.
